(19) United States
(12) Patent Application Publication
(10) Pub. No.: US 2026/0182229 A1
(43) Pub. Date: Jun. 25, 2026

(54) ORGANIC LIGHT-EMITTING DISPLAY DEVICE

(71) Applicant: LG Display Co., Ltd., Seoul (KR)

(72) Inventors: Ji Su HAN, Paju-si (KR); Hyun Seung KIM, Paju-si (KR)

(73) Assignee: LG Display Co., Ltd., Seoul (KR)

(21) Appl. No.: 19/387,224

(22) Filed: Nov. 12, 2025

(30) Foreign Application Priority Data
Dec. 20, 2024 (KR) 10-2024-0192597

(51) Int. Cl. H10K 59/80; H10K 59/122; H10K 59/38

(52) U.S. Cl. CPC H10K 59/8792; H10K 59/122; H10K 59/38

(57) ABSTRACT

The present disclosure discloses an organic light-emitting display device including a substrate on which a plurality of sub-pixels are defined, and a plurality of light-emitting elements provided on the substrate corresponding to the sub-pixels. A bank is provided in a boundary area of the light-emitting elements to define a light emission area. A black matrix is disposed to overlap the bank and has a plurality of openings corresponding to the sub-pixels, and a color filter is provided in the openings of the black matrix. A plurality of structure columns are disposed within the black matrix and the color filter; and a plurality of reflective patterns provided on the plurality of structure columns. The reflective patterns may be formed on top surfaces and side surfaces of the structure columns, and the structure columns may be arranged at intervals in both the black matrix region and the color filter region.

### CROSS-REFERENCE TO RELATED APPLICATION

This application claims priority to and the benefit of Korean Patent Application No. 10-2024-0192597, filed Dec. 20, 2024, the disclosure of which is incorporated herein by reference in its entirety as if fully set forth herein.

### BACKGROUND

### Technical Field

The present disclosure relates to an organic light-emitting display device including structure columns with reflective patterns provided in a black matrix and a color filter.

### Description of the Related Art

An electroluminescence display may be divided into an inorganic light-emitting display device and an organic light-emitting display device according to a material of a light emission layer.

An active matrix type organic light-emitting display device includes a self-luminescent organic light emitting diode (hereinafter, referred to as “OLED”) and has advantages of a high response speed, high light emission efficiency, high luminance, and a wide viewing angle.

The organic light-emitting display device has an organic light emitting diode (hereinafter, referred to as “OLED”) formed in each pixel. The organic light-emitting display device has a high response speed, high light emission efficiency, high luminance, and a wide viewing angle, and is excellent in contrast ratio and color reproducibility since a black grayscale can be expressed as complete black.

The description provided in the discussion of the related art section should not be assumed to be prior art merely because it is mentioned in or associated with that section. The discussion of the related art section may include information that describes one or more aspects of the subject technology, and the description in this section does not limit the disclosure.

### BRIEF SUMMARY

Recently, as people's interest in a flexible and slim display device has increased, a display device to which a relatively thin polarizing film is applied instead of a thick polarizing plate has been suggested. However, the coated polarizing film also has a large thickness, and when the thickness of the polarizing film is reduced, there is a problem that the function of the polarizing film and display quality are lowered.

For this reason, a color filter on encapsulation layer (CoE) structure has been suggested instead of the polarizing plate or the coated polarizing film. In the related art, the CoE structure is a structure in which a black matrix is provided on an encapsulation layer corresponding to a non-light emission area, and a color filter is provided corresponding to a light emission area. Such a CoE structure enables easy adjustment of transmittance while achieving reduction in thickness of the display device, and can improve display quality by absorbing external light and reflected light without causing a decrease in light emission efficiency.

However, since light that is emitted to the front is emitted in the same regardless of a position, a viewing angle luminance may be reduced and color shift may occur.

Embodiments of the present disclosure are directed to an organic light-emitting display device capable of improving luminance by reflecting and recycling part of light incident via metal structure columns to reflect part of light absorbed by a black matrix.

The problems addressed by the exemplary embodiments of the present disclosure are not limited to those described above, and other problems not described will be clearly understood by those skilled in the art from the following description.

An organic light-emitting display device according to an embodiment of the present disclosure includes a substrate on which a plurality of sub-pixels are defined; a plurality of light-emitting elements provided on the substrate corresponding to the plurality of sub-pixels; a bank that is provided in a boundary area of the plurality of light-emitting elements and defines a light emission area; a black matrix overlapping the bank and having a plurality of openings; a color filter that provided in the plurality of openings of the black matrix; a plurality of structure columns provided in the black matrix and the color filter; and a plurality of reflective patterns provided on the plurality of structure columns.

An organic light-emitting display device according to another embodiment of the present disclosure includes a substrate on which a plurality of sub-pixels are defined; a plurality of light-emitting elements provided on the substrate corresponding to the plurality of sub-pixels; an encapsulation layer provided on the plurality of light-emitting elements; a black matrix that is provided on the encapsulation layer and has a plurality of openings corresponding to the plurality of light-emitting elements; a plurality of color filters provided in the plurality of openings; a plurality of structure columns provided in the black matrix and the plurality of color filters; and a plurality of reflective patterns provided on the plurality of structure columns.

An organic light-emitting display device according to yet another embodiment of the present disclosure includes a bank defining a light emission area of the organic light-emitting display device; a black matrix overlapping the bank and having a plurality of openings; a color filter provided in the plurality of openings of the black matrix; a plurality of structure columns provided in the black matrix and the color filter; and a plurality of reflective patterns provided on the plurality of structure columns.

Details according to various exemplary embodiments of the present disclosure in addition to the solutions of the above problems are included in the following description and the drawings.

According to the exemplary embodiments of the present disclosure, it is possible to recycle light vertically downward by reflecting part of light emitted from the light-emitting elements via the reflective patterns on the metal structure columns.

According to the exemplary embodiments of the present disclosure, it is possible to improve luminance by reflecting and condensing part of light absorbed by the black matrix out of light emitted from the light-emitting elements via the reflective patterns on the structure columns in the black matrix.

According to the exemplary embodiments of the present disclosure, it is possible to improve viewing angle characteristics as the height of the structure columns in the black matrix increases.

According to the exemplary embodiments of the present disclosure, as the interval between the structure columns in the color filter area is smaller and the height of the structure column is smaller, front luminance can be higher.

Additionally, the organic light-emitting display device described herein is capable of improving luminance by reflecting and recycling part of light incident via metal structure columns to reflect part of light absorbed by a black matrix.

The effects of the present disclosure are not limited to the effects described above, and other effects not described will be understood by those skilled in the art to which the technical idea of the present disclosure belongs, from the following description.

### BRIEF DESCRIPTION OF THE SEVERAL VIEWS OF THE DRAWINGS

The above and other objects, features, and advantages of the present disclosure will become more apparent to those of ordinary skill in the art by describing exemplary embodiments thereof in detail with reference to the attached drawings, in which:

FIG. 1 is a plan view of an organic light-emitting display device according to a first exemplary embodiment of the present disclosure;

FIG. 2 is an enlarged plan view of one pixel of the organic light-emitting display device according to the first exemplary embodiment of the present disclosure;

FIG. 3 is a cross-sectional view taken along line I-I′ in FIG. 2;

FIG. 4 is an enlarged cross-sectional view of an A portion in FIG. 3;

FIG. 5 is an enlarged cross-sectional view of a B portion in FIG. 3;

FIG. 6 is a cross-sectional view of structure columns and reflective patterns provided in lower portions of a black matrix and a color filter layer in the organic light-emitting display device according to the first exemplary embodiment of the present disclosure on an enlarged scale;

FIG. 7 is an enlarged cross-sectional view of the A portion in FIG. 3 and is a cross-sectional view illustrating traveling states in transmission and reflection of light;

FIG. 8 is a cross-sectional view of the structure columns and the reflective patterns provided in the lower portion of the black matrix in the organic light-emitting display device according to the first exemplary embodiment of the present disclosure;

FIG. 9 is a graph illustrating viewing angle characteristics according to heights of the structure columns and the reflective patterns in the black matrix in the organic light-emitting display device according to the first exemplary embodiment of the present disclosure;

FIG. 10 is an enlarged graph of a C portion in FIG. 9;

FIG. 11 is an enlarged cross-sectional view of structure columns and reflective patterns in a color filter in the organic light-emitting display device according to the first exemplary embodiment of the present disclosure;

FIG. 12 is a graph illustrating wavelength-specific reflection of light according to an interval between the structure columns in the color filter in the organic light-emitting display device according to the first exemplary embodiment of the present disclosure;

FIG. 13 is a cross-sectional view taken along line I-I′ in FIG. 2 and is a cross-sectional view according to a second exemplary embodiment of the present disclosure;

FIG. 14 is an enlarged cross-sectional view of a D portion in FIG. 13;

FIG. 15 is an enlarged cross-sectional view of an E portion in FIG. 13;

FIG. 16 is a cross-sectional view taken along line I-I′ in FIG. 2 and is a cross-sectional view according to a third exemplary embodiment of the present disclosure;

FIG. 17 is an enlarged cross-sectional view of an F portion in FIG. 16; and

FIG. 18 is an enlarged cross-sectional view of a G portion in FIG. 16.

Throughout the drawings and the detailed description, unless otherwise described, the same drawing reference numerals should be understood to refer to the same elements, features, and structures.

### DETAILED DESCRIPTION

Reference will now be made in detail to embodiments of the present disclosure, examples of which may be illustrated in the accompanying drawings. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

The advantages and features of the present disclosure, and methods of achieving them will become apparent upon reference to the exemplary embodiments described in detail below in conjunction with the accompanying drawings. However, the present disclosure is not limited to the following exemplary embodiments disclosed herein, but may be implemented in various different forms; rather, these exemplary embodiments are provided to make the disclosure of the present disclosure complete and to enable those skilled in the art to fully comprehend the scope of the present disclosure.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Identical reference numerals may designate identical components throughout the description. Further, in describing the present disclosure, detailed descriptions of related known technologies may be omitted so as not to obscure the aspects of the present disclosure. The terms such as “including,” “having,” “consisting of” “make up of,” “formed of,” and the like as used herein are generally intended to allow other components to be added unless the terms are used with the term “only.” References to components of a singular noun include the plural of that noun, unless specifically stated otherwise.

In the interpretation of components, they are construed to include margins of error, even if not explicitly stated. Any implementation described herein as an “example” is not necessarily to be construed as preferred or advantageous over other implementations.

When describing a positional relationship, for example, “on top of,” “above,” “below,” “next to,” or “adjacent to” describes the positional relationship of two parts, one or more other parts may be located between the two parts, unless “immediately,” “directly,” or “near to” is used. For example, where an element or layer is disposed “on” another element or layer, a third layer or element may be interposed therebetween.

When describing a temporal relationship, “after,” “subsequently to,” “following,” or, “before” describes a temporal antecedent or consequent relationship, which may not be continuous unless “immediately,” or “directly” is used.

Terms such as first, second, A, B, (a), or (b) may be used to describe elements of the exemplary embodiments of the present disclosure. Such terms are intended only to distinguish one component from another and are not intended to define the nature, sequence, order, or number of such components. For example, a first element could be termed a second element, and, similarly, a second element could be termed a first element, without departing from the scope of the present disclosure.

When a component is described as being “connected,” “coupled,” “accessed,” or “attached” to another component, it is to be understood that the component may be directly connected, coupled, accessed, or attached to the other component, but that there may also be other components interposed between the respective components which may be indirectly connected, coupled, accessed, or attached, unless specifically stated otherwise.

When a component is described as being “in contacted” or “overlapped” with another component, it is to be understood that the component may be in direct contacted or overlap with the other component, but that there may also be other components “interposed” between the respective components which may be indirect contacted or overlap with, unless specifically stated otherwise.

To further elaborate, as used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

It should be understood that the term “at least one” includes all possible combinations of one or more related components. For example, the meaning of “at least one of the first, second, and third components” may be understood to include not only the first, second, or third component, but also any combination of two or more of the first, second, and third components.

The terms “the first direction,” “the second direction,” “the third direction,” “the X-axis direction,” “the Y-axis direction,” and “the Z-axis direction” are not to be interpreted solely as a geometric relationship in which the relationship to one another is perpendicular, but may refer to a broader range of orientations in which the configurations of the present disclosure may function.

As used herein, “a device” may include a display device, such as a liquid crystal module (LCM) or an organic light-emitting diode (OLED) module, which includes a display panel and a driver for driving the display panel. It may also include a set electronic apparatus or a set device, such as a laptop computer, a television set, a computer monitor, a vehicle or an automotive apparatus, or an equipment apparatus including another form of vehicle, and a mobile electronic apparatus, such as a smart phone or an electronic pad and the like, which is a complete product or finished product including LCMs, OLED modules, and the like.

Therefore, the device in the present disclosure may include a display device itself, such as an LCM module, OLED module, and the like, and a set device which is an application product or an end-consumer device including the LCM, OLED module, and the like.

Furthermore, in some embodiments, an LCM module and an OLED module composed of a display panel and a driver may be expressed as a display device, and an electronic device as a finished product including the LCM, OLED module (or panel) may be distinguished and expressed as a set device.

For example, the display device may include a liquid crystal display (LCD) panel or an organic light-emitting diode (OLED) display panel, and a source printed circuit board (PCB) which is a control part for driving the display panel. The set device may further include a set PCB, which is a set control part electrically connected to the source PCB to drive the entire set device.

The display panels used in the exemplary embodiments of the present disclosure may be any type of display panels such as a liquid crystal display panel, an organic light-emitting diode (OLED) display panel, and an electroluminescent display panel, but the exemplary embodiments are not limited thereto. For example, the display panel may be a display panel capable of generating sound by being vibrated by a vibration device according to the exemplary embodiments of the present disclosure. The display panel applied to the display device according to the exemplary embodiments of the present disclosure is not limited to the form or size of the display panel.

Each of the features of various embodiments of the present disclosure may be coupled or combined with one another in whole or in part, and may be technologically interlocked and operated in various ways, and each of the exemplary embodiments may be carried out independently or in conjunction with one another.

Hereinafter, various embodiments of the present disclosure will be described in detail with reference to the accompanying drawings. The scale of the components shown in the drawings has a different scale from the actual scale for convenience of explanation and is not limited to the scale shown in the drawings.

The display device of the present disclosure may be applied to various display devices such as an organic electroluminescent display device, an electrophoretic display device, a mini light-emitting diode (LED) display device, and a micro LED display device, but hereinafter, for convenience of explanation, an organic electroluminescent display device will be described as an example.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

The features of the various embodiments of the present disclosure may be partially or entirely combined with each other, and may be technically associated with each other or operate with each other. The embodiments may be implemented independently of each other and may be implemented together in an association relationship.

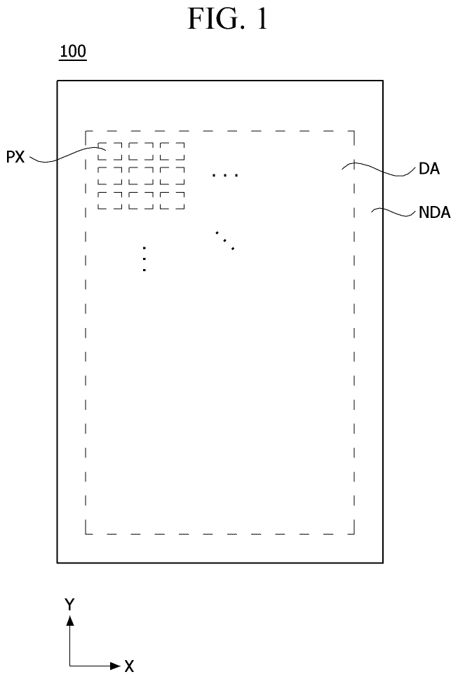

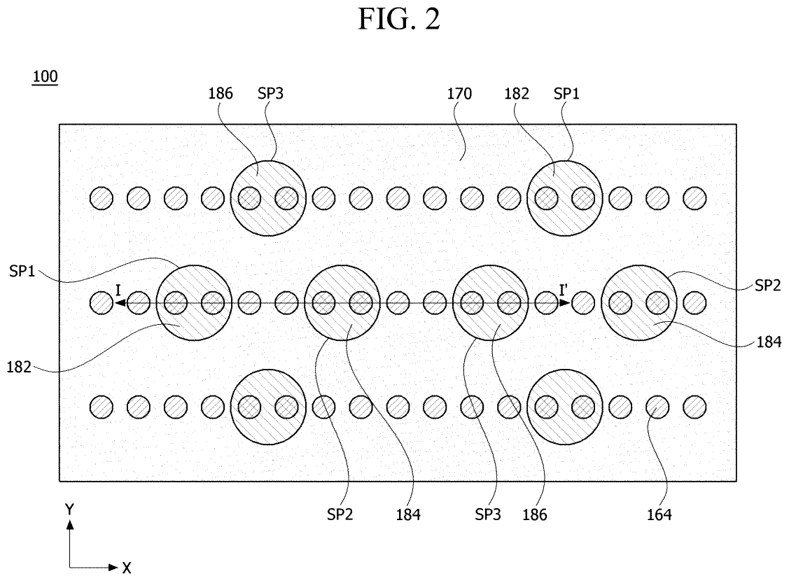

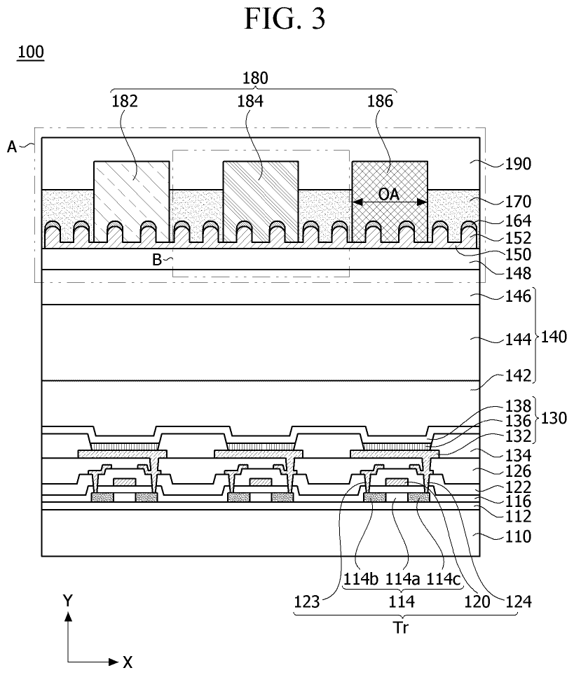

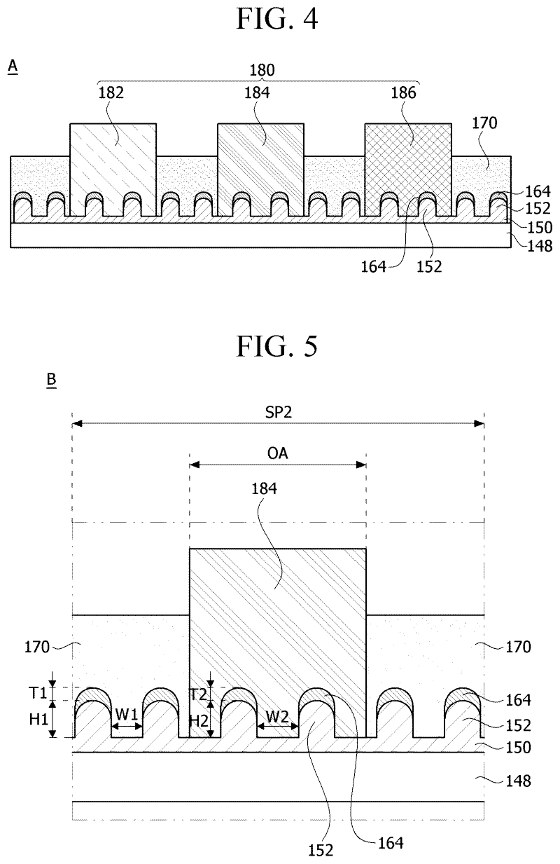

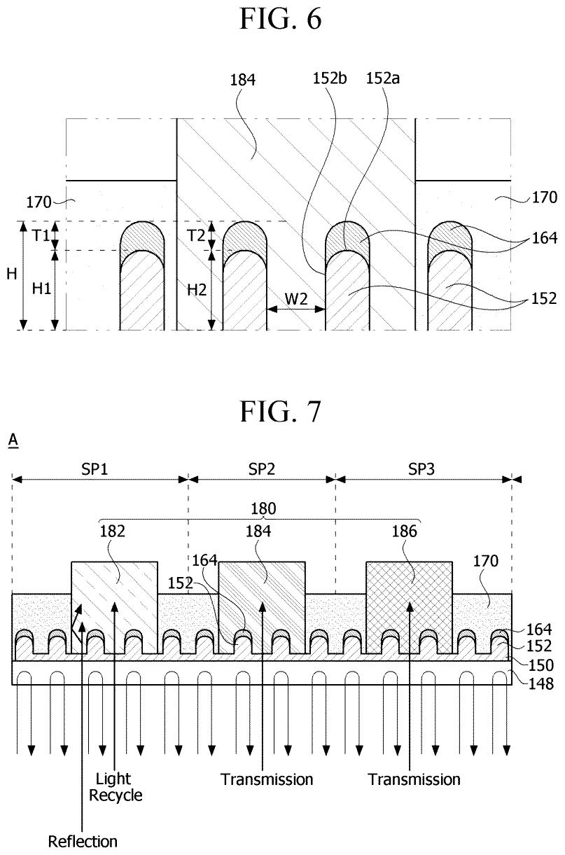

FIG. 1 is a plan view of an organic light-emitting display device according to a first exemplary embodiment of the present disclosure. FIG. 2 is an enlarged plan view of one pixel of the organic light-emitting display device according to the first exemplary embodiment of the present disclosure. FIG. 3 is a cross-sectional view taken along line I-I′ in FIG. 2. FIG. 4 is an enlarged cross-sectional view of an A portion in FIG. 3. FIG. 5 is an enlarged cross-sectional view of a B portion in FIG. 3. FIG. 6 is a cross-sectional view of structure columns and reflective patterns provided in lower portions of a black matrix and a color filter layer in the organic light-emitting display device the present disclosure on an enlarged scale.

Referring to FIGS. 1 to 6, an organic light-emitting display device 100 according to the first exemplary embodiment of the present disclosure may include a substrate 110, thin film transistors Tr, light-emitting elements 130, an encapsulation layer 140, a touch sensing part (not illustrated), a black matrix 170, and a color filter 180. For example, the color filter 180 may comprise a plurality of color filters 182, 184, and 186, but is not limited thereto.

The organic light-emitting display device 100 according to the first exemplary embodiment of the present disclosure may include areas defined as a display area DA and a non-display area NDA. The display area DA may be an area where a plurality of pixels PX are provided and an image is substantially displayed. In the display area DA, the pixels PX each including a light emission area for displaying an image and driving circuits for driving the pixels PX may be provided.

The non-display area NDA may refer to an area outside of the display area DA. The non-display area NDA may surround the display area DA. The non-display area NDA is an area where an image is not substantially displayed, and in the non-display area NDA, various wires, a driver IC, a printed circuit board, and the like for driving the pixels PX and the driving circuits provided in the display area DA may be provided. The non-display area NDA may be also referred to as an edge area or a bezel area.

The plurality of pixels PX are provided in a matrix, and each of the plurality of pixels PX may include a plurality of sub-pixels such as sub-pixels SP1, SP2, and SP3, but is not limited thereto. Each of the sub-pixels SP1, SP2, and SP3 may be an element for displaying one color, and may include a light emission area where light is emitted and a non-light emission area where light is not emitted.

In the present disclosure, only the light emission area where light is emitted may be defined as a sub-pixel. For example, each of a plurality of sub-pixels may display one color of red, green, and blue, but embodiments of the present disclosure are not limited thereto.

In another exemplary embodiment, each of a plurality of sub-pixels may display one color of cyan, magenta and yellow. In various embodiments, each of a plurality of sub-pixels may display one color of red, green, blue and white.

One pixel PX may include a plurality of sub-pixels, such as a first sub-pixel SP1, a second sub-pixel SP2, and a third sub-pixel SP3, but is not limited thereto. More or less sub-pixels may be possible. For example, the first sub-pixel SP1, the second sub-pixel SP2, and the third sub-pixel SP3 may be alternately arranged in a first direction (X-axis direction) and a second direction (Y-axis direction), but embodiments of the present disclosure are not limited thereto. The first sub-pixel SP1, the second sub-pixel SP2, and the third sub-pixel SP3 may be provided in a zigzag in the first direction (X axis) and the second direction (Y axis), but embodiments of the present disclosure are not limited thereto.

The first sub-pixel SP1, the second sub-pixel SP2, and the third sub-pixel SP3 may display different colors, and some sub-pixels may display the same color as necessary. For example, the first sub-pixel SP1 may be a red sub-pixel, the second sub-pixel SP2 may be a green sub-pixel, and the third sub-pixel SP3 may be a blue sub-pixel, but embodiments of the present disclosure are not limited thereto.

In the drawing, while the sub-pixels SP1, SP2, and SP3 of the same size are illustrated, the sub-pixels SP1, SP2, and SP3 may be formed to have different areas according to the colors displayed by the sub-pixels SP1, SP2, and SP3 in consideration of luminance and color temperature. For example, the third sub-pixel SP3 serving as a blue sub-pixel may have an area greater than the areas of the first sub-pixel SP1 and the second sub-pixel SP2. For example, the third sub-pixel SP3 serving as a blue sub-pixel may have an area greater than the areas of the first sub-pixel SP1 serving as the red sub-pixel and the second sub-pixel SP2 serving as the green sub-pixel, but embodiments of the present disclosure are not limited thereto. The second sub-pixel SP2 serving as the green sub-pixel may have an area greater than the area of the first sub-pixel SP1 serving as the red sub-pixel, but embodiments of the present disclosure are not limited thereto.

Each of the sub-pixels SP1, SP2, and SP3 may have a circular shape, an elliptical shape, a polygonal shape such as a triangular shape, a quadrangular shape, a pentagonal shape or a hexagonal shape, and is not particularly limited.

The substrate 110 is a substrate for supporting various elements that configure the display device. For example, the substrate 110 may be a plastic substrate. For example, the plastic substrate may be selected from polyimide, polyethersulfone, polyethylene terephthalate, and polycarbonate, but embodiments of the present disclosure are not limited thereto. When the plastic substrate having flexibility is used, a support member such as a back plate may be provided below the substrate 110. The plastic substrate having flexibility is relatively thin and weak in strength compared to a glass substrate, and may sag when various elements are provided thereon. The back plate supports the substrate 110 made of plastic such that the substrate 110 does not sag, and protects the display device 100 from moisture, heat, shock, or the like. For example, the back plate may be made of metal such as stainless steel (SUS) or may be made of plastic such as polymethylmethacrylate, polycarbonate, polyvinyl alcohol, acrylonitril-butadiene-styrene, or polyethylene terephthalate. When the back plate is provided below the substrate 110, an adhesive layer may be provided between the substrate 110 and the back plate to bond the substrate 110 and the back plate. The adhesive layer may be a light transparent adhesive or a pressure-sensitive adhesive, but embodiments of the present disclosure are not limited thereto.

A substrate buffer layer 112 may be provided on the substrate 110 to prevent penetration of oxygen or moisture. The substrate buffer layer 112 may be formed as a single layer or may be formed to have a multi-layer structure as necessary. A thin film transistor Tr including a gate electrode 120, an active layer 114, a source electrode 123, and a drain electrode 124 may be provided on the substrate buffer layer 112. The active layer 114 may include a channel area 114a, a source area 114b, and a drain area 114c.

The thin film transistor Tr may be provided in each of the first sub-pixel SP1, the second sub-pixel SP2, and the third sub-pixel SP3. In the drawing, for convenience of description, only a driving thin film transistor among various thin film transistors in the organic light-emitting display device 100 is illustrated.

In the drawing, while the thin film transistor Tr has a coplanar structure is described as an example, embodiments of the present disclosure are not limited thereto, and a thin film transistor Tr having an inverted staggered structure may also be used. For example, the active layer 114 may be provided on the substrate buffer layer 112, and a gate insulating layer 116 for insulating the active layer 114 from the gate electrode 120 may be provided on the active layer 114. For example, the gate insulating layer 116 may be disposed to cover the active layer 114 and a portion of the substrate buffer layer 112 exposed by the active layer 114. The active layer 114 may include the channel area 114a, and the source area 114b and the drain area 114c on both sides of the channel area 114a.

An interlayer insulating layer 122 for insulating the gate electrode 120 from the source electrode 123 and the drain electrode 124 may be provided on the gate insulating layer 116.

The source electrode 123 and the drain electrode 124 that are in contact with the source area 114b and the drain area 114c of the active layer 114, respectively, may be formed on the interlayer insulating layer 122.

A planarization layer 126 may be provided on the thin film transistor Tr. The planarization layer 126 may planarize an upper portion of the thin film transistor Tr. A contact hole for electrically connecting the thin film transistor Tr and an anode 132 of the light-emitting element 130 may be disposed in the planarization layer 126. The light-emitting element 130 may be provided on the planarization layer 126. The light-emitting element 130 may be provided in each of areas of a plurality of sub-pixels SP1, SP2, and SP3.

The planarization layer 126 may be formed of one or more materials of acrylic resin, epoxy resin, phenolic resin, polyamides resin, unsaturated polyesters resin, polyphenylene resin, polyphenylene sulfides resin, and benzocyclobutene, but embodiments are not limited thereto.

The light-emitting element 130 may include a plurality of light-emitting elements, and the plurality of light-emitting elements may be disposed in the plurality of sub-pixels. The light-emitting element 130 may include a first light-emitting element 130R provided in the first sub-pixel SP1, a second light-emitting element 130G provided in the second sub-pixel SP2, and a third light-emitting element 130B provided in the third sub-pixel SP3, but is not limited thereto. Each of the light-emitting elements 130R, 130G, and 130B may include the anode 132, an intermediate layer 136, and a cathode 138.

The anode 132 may be provided on the planarization layer 126. The anode 132 may be provided corresponding to each of the plurality of sub-pixels SP1, SP2, and SP3. The anode 132 is a component for supplying holes to the intermediate layer 136, and may be formed of a conductive material having a high work function. The anode 132 may be a transparent conductive layer formed of transparent conductive oxide (TCO). For example, the anode 132 may be formed of one or more selected from transparent conductive oxides such as indium-tin-oxide (ITO), indium-zinc-oxide (IZO), indium-tin-zinc oxide (ITZO), SnO2, ZnO, indium-copper-oxide (ICO), and Al-doped ZnO (AZO), but embodiments of the present disclosure are not limited thereto.

When the display device 100 is driven by a top emission method, the anode 132 may further include a reflective pattern to reflect light emitted from the intermediate layer 136 to the cathode 138 side. The anode 132 may be formed separately for each of the first sub-pixel SP1, the second sub-pixel SP2, and the third sub-pixel SP3, but embodiments of the present disclosure are not limited thereto.

A bank 134 may be provided on the anode 132 and the planarization layer 126. The bank 134 may be provided to cover an edge of the anode 132 of the light-emitting element 130. The bank 134 may be provided to cover an upper surface of the planarization layer 126. That is, the bank 134 may define the light emission area by covering the edge of the anode 132.

The banks 134 may partition the plurality of sub-pixels SP1, SP2, and SP3. The bank 134 may be made of an insulating material to insulate the anodes 132 of adjacent sub-pixels SP1, SP2, SP3. The bank 134 may be configured with a black bank having high light absorbance to prevent color mixture between adjacent sub-pixels SP1, SP2, and SP3. For example, the bank 134 may be made of polyimide resin, acrylic resin, or benzocyclobutene resin, but embodiments of the present disclosure are not limited thereto. The bank 134 may also be made of a transparent insulating material.

The cathode 138 may be provided on the bank 134 and the intermediate layer 136. The cathode 138 may be formed of a metal material having a low work function to smoothly supply electrons to the intermediate layer 136. For example, the cathode 138 may be formed of a metal material selected from calcium (Ca), barium (Ba), aluminum (Al), silver (Ag), and an alloy including one or more of calcium, barium, aluminum, and silver, but embodiments of the present disclosure are not limited thereto.

The cathode 138 may be formed as one layer on the anode 132. That is, the cathode 138 may be formed as a single layer in the first sub-pixel SP1, the second sub-pixel SP2, and the third sub-pixel SP3. For example, the cathode 138 may be formed as a common layer in the first sub-pixel SP1, the second sub-pixel SP2, and the third sub-pixel SP3, but embodiments of the present disclosure are not limited thereto. When the organic light-emitting display device 100 is driven by the top emission method, the cathode 138 may be formed at a very thin thickness and may be formed substantially transparent.

The intermediate layer 136 may be provided between the anode 132 and the cathode 138. The intermediate layer 136 is a layer where electrons and holes are coupled to emit light. For example, the intermediate layer 136 may be separated for each of the plurality of sub-pixels SP1, SP2, and SP3. In this case, the intermediate layer 136 may be configured to emit light of the same color as the corresponding sub-pixel. For example, the intermediate layer of the first light-emitting element 130R may be a red intermediate layer, the intermediate layer of the second light-emitting element 130G may be a green intermediate layer, and the intermediate layer of the third light-emitting element 130B may be a blue intermediate layer. However, embodiments of the present disclosure are not limited thereto.

For example, the intermediate layer 136 may include one or more of a hole injection layer (HIL), a hole transmitting layer (HTL), an electron transmitting layer (ETL) and an electron injection layer (EIL), but the present disclosure is not limited thereto.

As another example, the intermediate layer 136 may not be separated for each of the plurality of sub-pixels SP1, SP2, and SP3, and may be formed as a common layer. In this case, the intermediate layer 136 may be configured to emit white light and light of the colors corresponding to the respective sub-pixels SP1, SP2, and SP3 may be emitted via a color filter 180.

To improve light emission efficiency, the light-emitting element 130 may further include a hole injection layer, a hole transport layer, an electron transport layer, an electron injection layer, and the like. For example, the hole injection layer and the hole transport layer may be provided between the anode 132 and the intermediate layer 136, and the electron transport layer and the electron injection layer may be provided between the intermediate layer 136 and the cathode 138. To further improve re-coupling efficiency in the intermediate layer 136, a hole blocking layer or an electron blocking layer may be provided.

An encapsulation layer 140 may be provided on the light-emitting element 130. The encapsulation layer 140 may cover the light-emitting element 130. The encapsulation layer 140 may protect the light-emitting element 130 from external moisture, oxygen, shock, or the like. The encapsulation layer 140 may be formed to have a multi-layer structure in which an inorganic layer formed of an inorganic insulating material and an organic layer formed of an organic material are stacked, but embodiments of the present disclosure are not limited thereto. Alternatively, the encapsulation layer 140 may be formed as a single layer. For example, the encapsulation layer 140 may be configured with at least one organic layer and at least two inorganic layers and may have a multi-layer structure in which an inorganic layer and an organic layer are stacked alternately, but embodiments of the present disclosure are not limited thereto. For example, the encapsulation layer 140 may have a three-layer structure including a first passivation layer 142, an organic layer 144, and a second passivation layer 146, but embodiments of the present disclosure are not limited thereto. For example, the organic layer 144 may be disposed between the first passivation layer 142 and the second passivation layer 146. In this case, the first passivation layer 142 and the second passivation layer 146 may be independently formed of one or more selected from silicon nitride (SiNx), silicon oxide (SiOx), aluminum oxide (AlOx), and silicon oxy nitride (SiON), but embodiments of the present disclosure are not limited thereto.

The organic layer 144 may be formed of one or more selected from epoxy resin, polyimide, polyethylene, and silicon oxy carbide (SiOC), but embodiments of the present disclosure are not limited thereto.

A touch buffer layer 148 may be provided on the second passivation layer 146. The touch buffer layer 148 may be provided on the entire surface of the substrate 110 across the display area DA and the non-display area NDA. For this reason, the touch buffer layer 148 can protect the light-emitting elements 130, and signal wires, a pad part, and the like provided in the non-display area NDA to drive the light-emitting elements 130 from damage in forming a plurality of touch electrodes.

The touch buffer layer 148 may be formed of an inorganic insulating material, and may be formed of, for example, one or more selected from silicon nitride (SiNx), silicon oxide (SiOx), aluminum oxide (AlOx), and silicon oxy nitride (SiON), but embodiments of the present disclosure are not limited thereto.

A plurality of touch electrodes may be a layer including electrodes for sensing a touch input, may be configured with a plurality of sensing electrodes and a plurality of driving electrodes, and may sense touch coordinates by sensing change in capacitance between the electrodes. For example, the sensing electrodes and the driving electrodes may be provided on the same plane, and at least some of the plurality of touch electrodes may be electrically connected via a bridge electrode provided on a plane different from that the touch electrodes with an insulating layer interposed therebetween. However, embodiments of the present disclosure are not limited thereto, and the configuration of the touch sensor part may be changed in various ways as necessary.

Each of the plurality of touch electrodes may be provided corresponding to a boundary of the sub-pixels. In this case, the efficiency of light emitted from the light-emitting element 130 can be maintained high without being lowered, and display quality can be excellent since the touch electrodes are not visible from the outside.

An organic material layer 150 including a plurality of structure columns 152 that protrude in a vertical direction at regular intervals may be provided on the touch buffer layer 148. For example, the plurality of structure columns 152 may be provided in the black matrix 170 and the color filter 180. The organic material layer 150 may be formed of one or more selected from acrylic resin, epoxy resin, polyimide, polyethylene, and silicon oxy carbide (SiOC), but embodiments of the present disclosure are not limited thereto. In this case, the structure columns 152 of the organic material layer 150 may be formed by coating the organic material layer 150 on the touch buffer layer 148, molding a structure column form in the organic material layer 150, and then, performing UV curing.

Referring to FIG. 6, a plurality of reflective patterns 164 may be provided on the surfaces of the plurality of structure columns 152. Specifically, the plurality of reflective patterns 164 may be formed on top surfaces 152a and side surfaces 152b of the plurality of structure columns 152. However, embodiments of the present disclosure are not limited thereto. The reflective patterns 164 may include low-resistance metal such as silver (Ag), aluminum (Al), copper (Cu), chromium (Cr), or nickel (Ni), or may include a conductive nano-material such as silver nanowire or carbon nanotube. Specifically, the reflective patterns 164 may be preferably formed of a conductive material having excellent reflection characteristics. However, embodiments of the present disclosure are not limited thereto.

Referring to FIG. 6, the reflective patterns 164 may be formed by depositing a metal material on the structure columns 152 vertically downward and obliquely at a given angle. The reflective patterns 164 may be formed on the top surfaces 152a and the side surfaces 152b of the structure columns 152. However, embodiments of the present disclosure are not limited thereto.

The black matrix 170 that covers the plurality of structure columns 152 and the plurality of reflective patterns 164 may be provided on the organic material layer 150. The black matrix 170 may serve as an anti-reflection layer that absorbs external light while maintaining luminance of light emitted from the light-emitting elements 130 high and minimizes reduction in visibility and contrast ratio of the organic light-emitting display device 100 due to external light.

The black matrix 170 may absorb external light. Accordingly, it is possible to minimize reduction in visibility and contrast ratio of the organic light-emitting display device 100 due to external light. The black matrix 170 may include base resin and a black material. For example, the base resin may be one or more selected from cardo-based resin, epoxy-based resin, acrylate-based resin, siloxane-based resin, and polyimide, but embodiments of the present disclosure are not limited thereto. The black material may be a black pigment selected from a carbon-based pigment, a metal oxide-based pigment, and an organic-based pigment. For example, the carbon-based pigment may be carbon black. For example, the metal oxide-based pigment may be titanium black (TiNxOy) or a Cu—Mn—Fe-based black pigment, but embodiments of the present disclosure are not limited thereto. For example, the organic-based pigment may be selected from lactam black, perylene black, and aniline black, but embodiments of the present disclosure are not limited thereto. Further, an RGB black pigment including a red pigment, a blue pigment, and a green pigment may be used as the black material, but embodiments of the present disclosure are not limited thereto.

The black matrix 170 may cover at least one structure column 152 and reflective pattern 164. The black matrix 170 may be provided along the boundary of the sub-pixels SP1, SP2, and SP3. The black matrix 170 may be provided to overlap the banks 134. Accordingly, it is possible to minimize color mixture between the sub-pixels SP1, SP2, and SP3.

The black matrix 170 may include a plurality of openings OA. The plurality of openings OA may overlap the plurality of sub-pixels SP1, SP2, and SP3, respectively. The plurality of openings OA may overlap the light emission areas of the plurality of sub-pixels SP1, SP2, and SP3, respectively, to transmit light emitted from the intermediate layers 136. For example, the black matrix 170 may be provided to overlap the banks 134, and the plurality of openings OA disposed between the black matrix 170 may overlap the light emission areas of the plurality of sub-pixels SP1, SP2, and SP3, respectively.

The organic light-emitting display device 100 may have a pull-back structure. Specifically, a width of the opening OA may be greater than a width of the light emission area. However, embodiments of the present disclosure are not limited thereto.

A width of the bank 134 that defines the light emission areas of the plurality of sub-pixels SP1, SP2, and SP3 may be greater than a width of the black matrix 170 that defines the openings OA. Accordingly, the width of the opening OA may be greater than a width of each of the sub-pixels SP1, SP2, and SP3. In this case, since part of light emitted from the light-emitting element 130 may be output to the side surface, a viewing angle luminance and a color viewing angle can be excellent. However, embodiments of the present disclosure are not limited thereto.

A plurality of color filters 180 may be provided on the organic material layer 150 positioned in the openings OA of the black matrix 170. For example, in the openings OA of the black matrix 170, the plurality of color filters 180 may be provided on the organic material layer 150. Each of plurality of color filters 180 may include a first color filter 182, a second color filter 184, and a third color filter 186, but is not limited thereto.

Here, at least one structure column 152 may be provided in lower portions of the first to third color filters 182, 184, and 186. In this case, the structure column 152 may be formed to protrude from a top surface of the organic material layer 150 in the vertical direction. For example, the at least one structure column 152 may be provided in lower portions of the black matrix 170 and the first to third color filters 182, 184, and 186.

Referring to FIGS. 5 and 6, at least one structure column 152 and at least one reflective pattern 164 may be provided in the black matrix 170 and the color filters 182, 184, and 186. A total height H of the structure column 152 and the reflective pattern 164 in the black matrix 170 may be a sum of a first height of the structure column 152 and a first thickness T1 of the reflective pattern 164. The structure columns 152 in the black matrix 170 may be spaced apart from each other at a first interval W1.

A total height H of the structure column 152 and the reflective pattern 164 in the color filters 182, 184, and 186 may be a sum of a second height of the structure column 152 and a second thickness T2 of the reflective pattern 164. The structure columns 152 in the color filters 182, 184, and 186 may be spaced apart from each other at a second interval W2.

Here, the first height H1 and the second height H2 of the structure columns 152 in the black matrix 170 and the color filters 182, 184, and 186 may be the same. The first thickness T1 and the second thickness T2 of the reflective patterns 164 in the black matrix 170 and the color filters 182, 184, and 186 may be the same. The first interval W1 and the second interval W2 of the structure columns 152 in the black matrix 170 and the color filters 182, 184, and 186 may also be the same. However, embodiments of the present disclosure are not limited thereto.

The reflective pattern 164 may be provided on the structure column 152. The reflective pattern 164 may be formed on the top surface and the side surface of the structure column 152. For example, the reflective pattern 164 may be formed on the top surface and the side surface of the structure column 152 in the black matrix 170 and the color filters 182, 184, and 186.

The plurality of color filters 182, 184, and 186 may include the first color filter 182 corresponding to the first sub-pixel SP1, the second color filter 184 corresponding to the second sub-pixel SP2, and the third color filter 186 corresponding to the third sub-pixel SP3.

Each of the plurality of color filters 182, 184, and 186 may be a circular shape on a plane, but embodiments of the present disclosure are not limited thereto. As another example, each of the plurality of color filters 182, 184, and 186 may be an elliptical shape or may be a polygonal shape such as a triangular shape, a quadrangular shape, a pentagonal shape, or a hexagonal shape, and is not particularly limited.

The respective color filters 182, 184, and 186 may correspond to the colors of the corresponding sub-pixels SP1, SP2, and SP3. That is, when the first sub-pixel SP1 is a red sub-pixel, the first color filter 182 may be a red color filter, when the second sub-pixel SP2 is a green sub-pixel, the second color filter 184 may be a green color filter, and when the third sub-pixel SP3 is a blue sub-pixel, the third color filter 186 may be a blue color filter.

The first color filter 182 may transmit red light. Here, a wavelength of the red light may be about 620 nm to 750 nm, but embodiments of the present disclosure are not limited thereto. The second color filter 184 may transmit green light. Here, a wavelength of the green light may be about 495 nm to 570 nm, but embodiments of the present disclosure are not limited thereto. The third color filter 186 may transmit blue light. Here, a wavelength of the blue light may be about 440 nm to 495 nm, but embodiments of the present disclosure are not limited thereto.

Each of the color filters 182, 184, and 186 may include transparent base resin and a color-development material. For example, the transparent base resin may be one or more selected from polyacrylate, polymethylmethacrylate, polyimide, polyvinyl alcohol, polyethylene, polypropylene, polystyrene, and polyethylene terephthalate, but embodiments of the present disclosure are not limited thereto. The color-development material absorbs light in a specific wavelength band and transmits light in remaining wavelength bands. For example, the red color filter may include a red color-development material that transmits light in a red wavelength band and absorbs light in green and blue wavelength bands.

The plurality of color filters 182, 184, and 186 may be provided corresponding to the light emission areas of the corresponding sub-pixels SP1, SP2, and SP3.

Accordingly, internal light emitted from the first sub-pixel SP1, the second sub-pixel SP2, and the third sub-pixel SP3 may be transmitted through the color filters 182, 184, and 186, respectively. For example, red light emitted from the first sub-pixel SP1 may be transmitted through the first color filter 182. For example, green light emitted from the second sub-pixel SP2 may be transmitted through the second color filter 184. For example, blue light emitted from the third sub-pixel SP3 may be transmitted through the third color filter 186.

On the other hand, when external light is incident, external light corresponding to an absorption wavelength of the color-development material included in each of the color filters 182, 184, and 186 may be absorbed by each of the color filters 182, 184, and 186. External light that is not absorbed by the color filters 182, 184, and 186 may be reflected by the cathodes 138 and transmitted through the color filters 182, 184, and 186 again. Reflected light corresponding to the absorption wavelengths of the color-development materials included in the respective color filters 182, 184, and 186 may be absorbed by the color filters 182, 184, and 186. Accordingly, it is possible to minimize reduction in display quality due to external light.

An overcoat layer 190 may be provided on the plurality of color filters 182, 184, and 186 and the black matrix 170 to cover the plurality of color filters 182, 184, and 186 and the black matrix 170. The overcoat layer 190 may planarize upper portions of the plurality of color filters 182, 184, and 186 and the black matrix 170. For example, the overcoat layer 190 may be formed of transparent resin such as acrylic resin, silicon-based resin, polyester-based resin, or epoxy resin, but embodiments of the present disclosure are not limited thereto.

FIG. 7 is an enlarged cross-sectional view of an A portion in FIG. 3 and is a cross-sectional view illustrating traveling states in transmission and reflection of light.

Referring to FIG. 7, light Light emitted from the plurality of light-emitting elements 130 may travel toward the plurality of color filters 182, 184, and 186. In this case, light emitted from the plurality of light-emitting elements 130 travels toward the plurality of color filters 182, 184, and 186, and light that is brought into contact with the portions of the plurality of structure columns 152 is reflected by the reflective patterns 164 provided on the surfaces of the structure columns 152 and recycled toward the light-emitting elements 130. As a result, it is possible to improve luminance. Then, the light Light emitted from the light-emitting elements 130 may be transmitted directly in the vertical direction via the areas of the color filters 182, 184, and 186 between the plurality of structure columns 152.

Part of the light Light emitted from the plurality of light-emitting elements 130 is brought into contact with the side surfaces of the reflective patterns 164 on the structure columns 152 in the color filters 182, 184, and 186 and is reflected. As a result, it is possible to improve the transmittance of light.

Out of the light Light emitted from the light-emitting elements 130, light incident on the structure columns 152 in the black matrix 170 positioned in the boundary areas of the plurality of color filters 182, 184, and 186 is reflected by the reflective patterns 164 on the structure columns 152 and recycled. As a result, it is possible to improve luminance.

Out of the light emitted from the light-emitting elements 130, light that is brought into contact with the side surfaces of the reflective patterns 164 on the structure columns 152 is reflected and transmitted through the color filters 182, 184, and 186. As a result, it is possible to improve the transmittance of light to improve luminance.

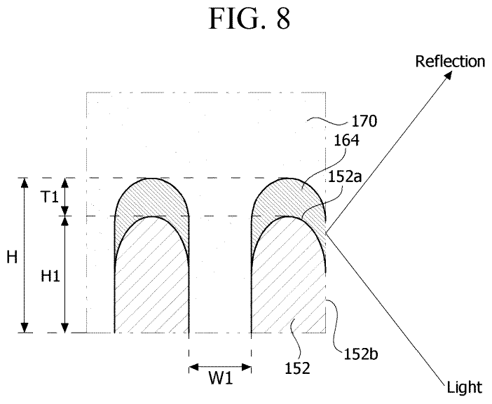

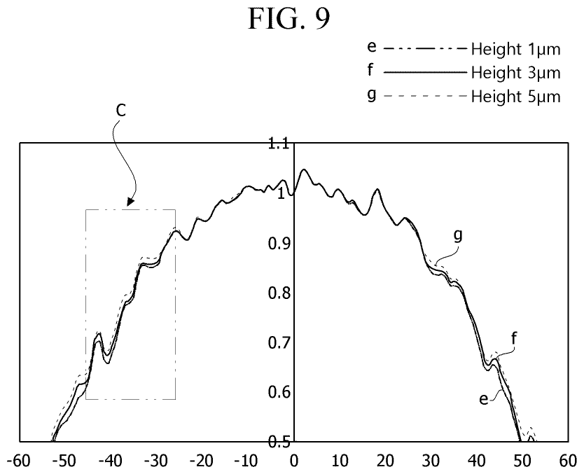

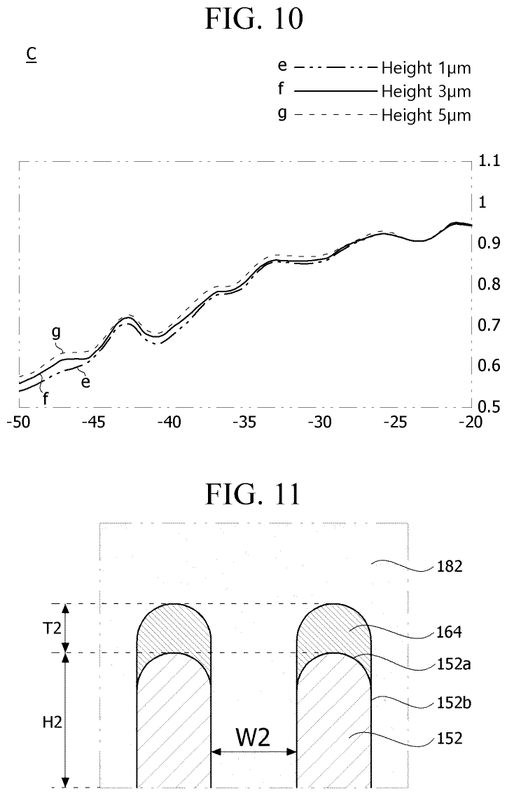

FIG. 8 is a cross-sectional view of the structure columns and the reflective patterns in the black matrix in the organic light-emitting display device according to the first exemplary embodiment of the present disclosure on an enlarged scale. FIG. 9 is a graph illustrating viewing angle characteristics according to the heights of the structure column and the reflective pattern in the black matrix in the organic light-emitting display device according to the first exemplary embodiment of the present disclosure. FIG. 10 is an enlarged graph of a C portion in FIG. 9.

Referring to FIG. 8, part of light emitted from the plurality of light-emitting elements 130 may be brought into contact with and reflected by the reflective patterns 164 on the structure columns 152 provided in the black matrix 170 positioned in the boundary areas of the plurality of color filters 182, 184, and 186. In this case, light reflected by the reflective pattern 164 is diffused toward the color filter 182, 184, or 186 in contact with the black matrix 170. As a result, it is possible to increase light transmittance in the color filters.

Referring to FIGS. 9 and 10, when the height H1 of the structure column 152 in the black matrix 170 is 1 μm (example—e), 3 μm (example—f), and 5 μm (example—g), in confirming viewing angle characteristics, it is possible to confirm that viewing angle characteristics are improved as the height H1 of the structure column 152 in the black matrix 170 increases.

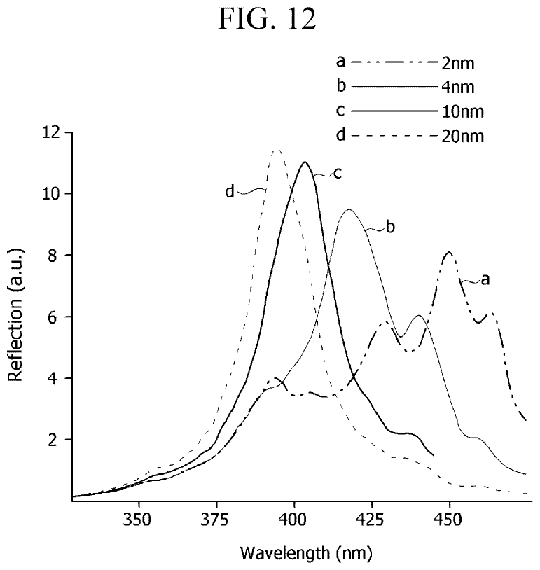

FIG. 11 is an enlarged cross-sectional view of the structure columns and the reflective patterns in the color filter in the organic light-emitting display device according to the first exemplary embodiment of the present disclosure. FIG. 12 is a graph illustrating wavelength-specific reflection according to an interval between the structure columns in the color filter in the organic light-emitting display device according to the first exemplary embodiment of the present disclosure.

For example, the structure columns 152 in the black matrix 170 may have the same height as or a height different from the structure columns 152 in the color filter 182, 184, or 186. For example, an interval between the structure columns 152 in the black matrix 170 is the same as or different from an interval between the structure columns 152 in the color filter 182, 184, or 186. Embodiments of the present disclosure are not limited thereto.

Referring to FIGS. 11 and 12, the thickness T2 of the reflective pattern 164 in the color filters 182, 184, and 186 may be maintained in a range of about 10 nm to 50 nm. For example, the thickness T2 of the reflective pattern 164 may be, for example, about 20 nm. Embodiments of the present disclosure are not limited thereto.

For example, when the height H2 of the structure column 152 in the color filter 182 is about 1 μm, front luminance can be shown as about 135%, 131%, and 136% with respect to the thickness T2 of the reflective pattern 164 of 10 nm, 1 μm, and 10 μm, respectively.

For example, when the height H2 of the structure column 152 in the color filter 182 is about 2 μm, front luminance can be shown as about 134%, 130%, and 135% with respect to the thickness T2 of the reflective pattern 164 of 10 nm, 1 μm, and 10 μm, respectively.

For example, when the height H2 of the structure column 152 in the color filter 182 is about 3 μm, front luminance can be shown as about 134%, 130%, and 135% with respect to the thickness T2 of the reflective pattern 164 of 10 nm, 1 μm, and 10 μm, respectively.

Referring to FIG. 12, as in ‘a,’ when the interval W2 between the structure columns 152 in the color filter 182 is about 2 nm, it can be understood that a reflection peak is shown as near about 8 (a.u.) at the wavelength of near about 430 to 450 nm.

As in ‘b,’ when the interval W2 between the structure columns 152 in the color filter 182 is about 4 nm, it can be understood that the reflection peak is shown as about 9 to 10 (a.u.) at the wavelength of near about 410 to 425 nm.

As in ‘c,’ when the interval W2 between the structure columns 152 in the color filter 182 is about 10 nm, it can be understood that the reflection peak is shown as about 10 to 11 (a.u.) at the wavelength of near about 400 nm.

As in ‘d,’ when the interval W2 between the structure columns 152 in the color filter 182 is 20 nm, it can be understood that the reflection peak is shown as about 11 (a.u.) at the wavelength of about 380 to 385 nm.

Referring to FIG. 12, when the interval W2 between the structure columns 152 in the red color filter 182 is adjusted to about 10 nm, it is possible to increase color reproducibility. In this case, the interval W2 between the structure columns 152 in the blue color filter 186 may be adjusted to about 10 nm, and the interval W2 between the structure columns 152 in the green color filter 184 may be adjusted to about 4 nm.

In this way, as the interval W2 between the structure columns 152 in the color filters 182, 184, and 186 is greater and the height H2 is higher, front luminance may be higher.

Referring to FIGS. 11 and 12, as the interval W2 between the structure columns 152 in the color filters 182, 184, and 186 is smaller, selective wavelength reflection may be made due to a plasmon resonance phenomenon. Accordingly, it is possible to increase color reproducibility by adjusting the interval W2 between the structure columns 152 in the color filter.

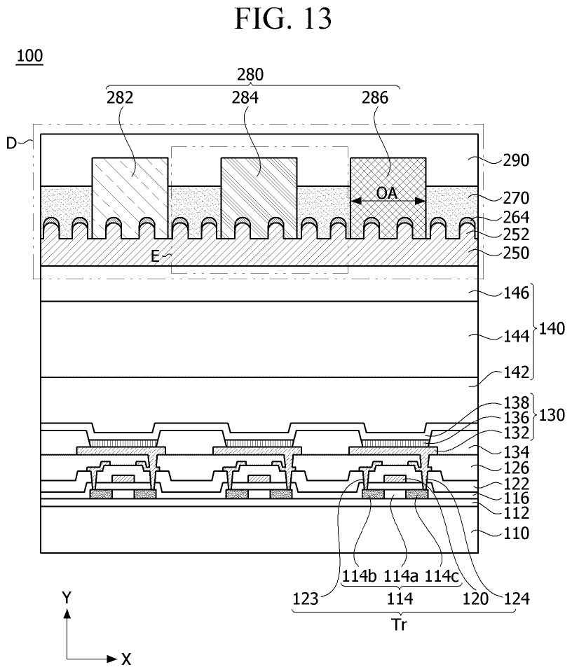

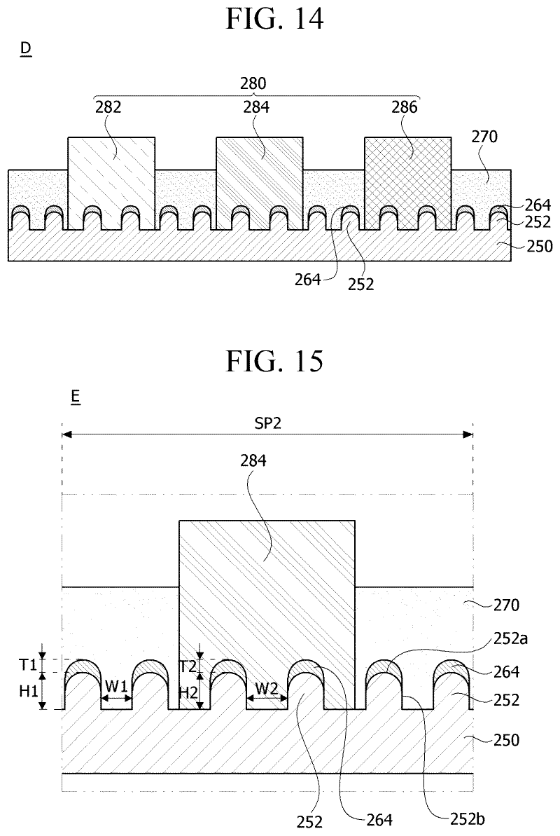

FIG. 13 is a cross-sectional view taken along line I-I′ in FIG. 2 and is a cross-sectional view according to a second exemplary embodiment of the present disclosure. FIG. 14 is an enlarged cross-sectional view of a D portion in FIG. 13. FIG. 15 is an enlarged cross-sectional view of an E portion in FIG. 13.

Referring to FIGS. 13 to 15, an organic light-emitting display device 100 according to the second exemplary embodiment of the present disclosure may include a substrate 110, thin film transistors Tr, light-emitting elements 130, an encapsulation layer 140, a touch buffer layer 250, structure columns 252 and reflective patterns 264, a black matrix 270, and a plurality of color filters 282, 284, and 286, but is not limited thereto. More or less components may be included.

The organic light-emitting display device 100 according to the second exemplary embodiment of the present disclosure may have the same configuration as or similar to the configuration according to the exemplary embodiment of the present disclosure, excluding that the structure columns 252 are integrated with the touch buffer layer 250. In the first exemplary embodiment of the present disclosure, since a step of further depositing the organic material layer 150 on the touch buffer layer 148 as an inorganic insulating layer as in FIG. 3 is required, the number of manufacturing steps may be increased accordingly.

In contrast, in the second exemplary embodiment of the present disclosure, the structure columns 252 are directly formed in the touch buffer layer 250 without additionally adding an organic material layer for forming the structure column 252, a step of forming an organic material layer is not required, and it is possible to simplify manufacturing steps accordingly.

Specifically, in the organic light-emitting display device 100 according to the second exemplary embodiment of the present disclosure, the configurations of the thin film transistors Tr, the light-emitting elements 130, the encapsulation layer 140, the reflective patterns 264, the black matrix 270, the color filters 282, 284, 286, and an overcoat layer 290 are the same as or similar to the configurations in the organic light-emitting display device 100 according to the exemplary embodiment of the present disclosure, and thus, detailed description thereof will not be repeated.

In the first exemplary embodiment of the present disclosure, the organic material layer 150 may be provided on the touch buffer layer 148. In the organic light-emitting display device 100 according to the second exemplary embodiment of the present disclosure, the touch buffer layer 250 may be provided on the second passivation layer 146 that configures the encapsulation layer 140. The touch buffer layer 250 may be provided on the entire surface of the substrate 110 across the display area DA and the non-display area NDA. For this reason, the touch buffer layer 250 can protect the light-emitting elements 130, and signal wires, a pad part, and the like provided in the non-display area NDA to drive the light-emitting elements 130 from damage in forming a plurality of touch electrodes.

The touch buffer layer 250 may be formed of an inorganic insulating material, and may be formed of, for example, one or more selected from silicon nitride (SiNx), silicon oxide (SiOx), aluminum oxide (AlOx), and silicon oxy nitride (SiON), but embodiments of the present disclosure are not limited thereto.

A plurality of touch electrodes may be a layer including electrodes for sensing a touch input, may be configured with a plurality of sensing electrodes and a plurality of driving electrodes, and may sense touch coordinates by sensing change in capacitance between the electrodes. For example, the sensing electrodes and the driving electrodes may be provided on the same plane, and at least some of the plurality of touch electrodes may be electrically connected via a bridge electrode provided on a plane different from that the touch electrodes with an insulating layer interposed therebetween. However, embodiments of the present disclosure are not limited thereto, and the configuration of the touch sensor part may be changed in various ways as necessary.

Each of the plurality of touch electrodes may be provided corresponding to a boundary of the sub-pixels. In this case, the efficiency of light emitted from the light-emitting element 130 can be maintained high without being lowered, and display quality can be excellent since the touch electrodes are not visible from the outside.

Referring to FIGS. 13 to 15, the touch buffer layer 250 may include a plurality of structure columns 252 that protrude from a top surface at regular intervals in a vertical direction. Here, the plurality of structure columns 252 may be integrated with the touch buffer layer 250.

A plurality of reflective patterns 264 may be provided on the surfaces of the plurality of structure columns 252. Specifically, the plurality of reflective patterns 264 may be formed across top surfaces 252a and side surfaces 252b of the plurality of structure columns 252. However, embodiments of the present disclosure are not limited thereto. The reflective pattern 264 may include low-resistance metal such as silver (Ag), aluminum (Al), copper (Cu), chromium (Cr), or nickel (Ni) or may include a conductive nano-material such as silver nanowire or carbon nanotube. Specifically, referring to FIG. 15, the reflective patterns 264 are preferably formed of a conductive material having excellent reflection characteristics. However, embodiments of the present disclosure are not limited thereto.

The reflective patterns 264 may be formed by depositing a metal material on the structure columns 252 vertically downward and obliquely at a given angle. The reflective patterns 264 may be formed the top surfaces 252a and the side surfaces 252b of the structure columns 252.

Referring to FIG. 15, at least one structure column 252 and at least one reflective pattern 264 may be provided in the black matrix 270 and the color filters 282, 284, and 286. The structure columns 252 in the black matrix 270 may have a first height H1, and the reflective patterns 264 may have a first thickness T1. The structure columns 252 in the black matrix 270 may be spaced apart from each other at a first interval W1.

Referring to FIG. 15, the structure columns 252 in the color filters 282, 284, and 286 may have a second height H2, and the reflective patterns 264 may have a second thickness T2. The structure columns 252 in the color filters 282, 284, and 286 may be spaced apart from each other at a second interval W2.

Here, the first height H1 and the second height H2 of the structure columns 252 in the black matrix 270 and the color filters 282, 284, and 286 may be the same. Here, the first thickness T1 and the second thickness T2 of the reflective patterns 264 in the black matrix 270 and the color filters 282, 284, and 286 may be the same. The first interval W1 and the second interval W2 of the structure columns 252 in the black matrix 270 and the color filters 282, 284, and 286 may also be the same. However, embodiments of the present disclosure are not limited thereto.

Alternatively, the first height H1 and the second height H2 of the structure columns 252 in the black matrix 270 and the color filters 282, 284, and 286 may be different. Here, the first thickness T1 and the second thickness T2 of the reflective patterns 264 in the black matrix 270 and the color filters 282, 284, and 286 may be different. The first interval W1 and the second interval W2 of the structure columns 252 in the black matrix 270 and the color filters 282, 284, and 286 may also be different. However, embodiments of the present disclosure are not limited thereto.

The black matrix 270 that covers the plurality of structure columns 252 and the plurality of reflective patterns 264 may be provided on the touch buffer layer 250. The black matrix 270 may serve as an anti-reflection layer that absorbs external light while maintaining luminance of light emitted from the light-emitting elements 130 high and minimizes reduction in visibility and contrast ratio of the organic light-emitting display device 100 due to external light.

The black matrix 270 may absorb external light. Accordingly, it is possible to minimize reduction in visibility and contrast ratio of the organic light-emitting display device 100 due to external light. The black matrix 270 may include base resin and a black material.

The black matrix 270 may cover at least one structure column 252 and reflective pattern 264. The black matrix 270 may be provided along the boundary of the sub-pixels SP1, SP2, and SP3. The black matrix 270 may be provided to overlap the bank 134. Accordingly, it is possible to minimize color mixture between the sub-pixels SP1, SP2, and SP3.

The black matrix 270 may include a plurality of openings OA. The plurality of openings OA may overlap a plurality of sub-pixels SP1, SP2, and SP3, respectively. The plurality of openings OA may overlap the light emission areas of the plurality of sub-pixels SP1, SP2, and SP3, respectively, to transmit light emitted from the intermediate layers 136.

The organic light-emitting display device 100 may have a pull-back structure. Specifically, a width of the opening OA may be greater than a width of the light emission area. However, embodiments of the present disclosure are not limited thereto.

A width of the bank 134 that defines the light emission areas of the plurality of sub-pixels SP1, SP2, and SP3 may be greater than a width of the black matrix 270 that defines the openings OA. Accordingly, the width of the opening OA may be greater than a width of each of the sub-pixels SP1, SP2, and SP3. In this case, since part of light emitted from the light-emitting element 130 may be output to the side surface, a viewing angle luminance and a color viewing angle can be excellent.

The color filters 282, 284, and 286 may be provided on the touch buffer layer 250 positioned in the openings OA of the black matrix 270. For example, in the openings OA of the black matrix 270, the plurality of color filters 280 may be provided on the touch buffer layer 250. A color filter 280 may include a first color filter 282, a second color filter 284, and a third color filter 286, but is not limited thereto.

Here, at least one structure column 252 may be provided in the first to third color filters 282, 284, and 286. In this case, the structure column 252 may be formed to protrude from a top surface of the touch buffer layer 250 vertically upward. For example, the at least one structure column 252 may be provided in lower portions of the black matrix 270 and the first to third color filters 182, 184, and 186.

The reflective patterns 264 may be provided on the structure columns 252. The reflective patterns 264 may be formed across top surfaces and side surfaces of the structure columns 252. For example, the reflective pattern 264 may be formed on the top surface and the side surface of the structure column 252 in the black matrix 270 and the color filters 282, 284, and 286.

The overcoat layer 290 may be provided on the plurality of color filters 282, 284, 286 and the black matrix 270 to cover the plurality of color filters 282, 284, and 286 and the black matrix 270. The overcoat layer 290 may planarize upper portions of the plurality of color filters 282, 284, and 286 and the black matrix 270. For example, the overcoat layer 290 may be formed of transparent resin such as acrylic resin, silicon-based resin, polyester-based resin, or epoxy resin, but embodiments of the present disclosure are not limited thereto.

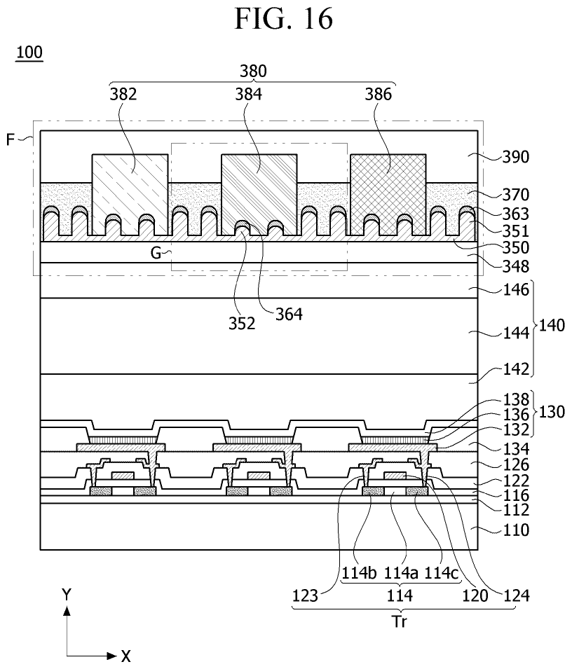

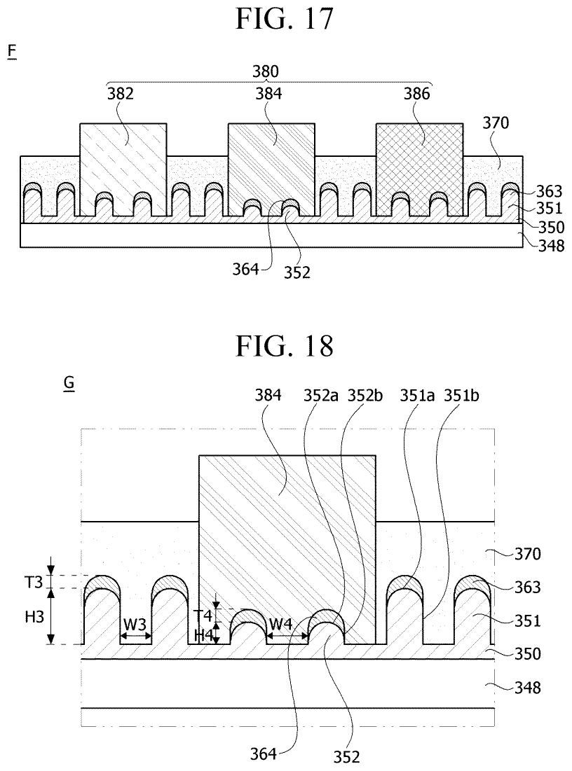

FIG. 16 is a cross-sectional view taken along line I-I′ in FIG. 2 and is a cross-sectional view according to a third exemplary embodiment of the present disclosure. FIG. 17 is an enlarged cross-sectional view of an F portion in FIG. 16. FIG. 18 is an enlarged cross-sectional view of a G portion in FIG. 16.

Referring to FIGS. 16 to 18, an organic light-emitting display device 100 according to the third exemplary embodiment of the present disclosure may include a substrate 110, thin film transistors Tr, light-emitting elements 130, an encapsulation layer 140, a touch buffer layer 348, an organic material layer 350, structure columns 351 and 352 and reflective patterns 363 and 364, a black matrix 370, and a plurality of color filters 382, 384, and 386, but is not limited thereto. More or less components may be included.

In the organic light-emitting display device 100 according to the third exemplary embodiment of the present disclosure, the configurations of the substrate 110, the thin film transistors Tr, the light-emitting elements 130, the encapsulation layer 140, the black matrix 370, and the plurality of color filters 382, 384, and 386 are the same as the configurations in the organic light-emitting display device according to the exemplary embodiment of the present disclosure, and thus, description thereof will not be repeated.

Here, the configurations of the touch buffer layer 348, the organic material layer 350, and the structure columns 351 and 352 and the reflective patterns 363 and 364 will be described.

Referring to FIGS. 16 to 18, the touch buffer layer 348 may be provided on the second passivation layer 146 that is provided as an uppermost layer of the encapsulation layer 140. The touch buffer layer 348 may be provided on the entire surface of the substrate 110 across the display area DA and the non-display area NDA. For this reason, the touch buffer layer 348 can protect the light-emitting elements 130, and signal wires, a pad part, and the like provided in the non-display area NDA to drive the light-emitting elements 130 from damage in forming a plurality of touch electrodes.

The touch buffer layer 348 may be formed of an inorganic insulating material, and may be formed of, for example, one or more selected from silicon nitride (SiNx), silicon oxide (SiOx), aluminum oxide (AlOx), and silicon oxy nitride (SiON), but embodiments of the present disclosure are not limited thereto.

The organic material layer 350 having a plurality of structure columns 351 and 352 that protrude at regular intervals in the vertical direction may be provided on the touch buffer layer 348. For example, the plurality of structure columns 351 and 352 may be provided in the black matrix 370 and the color filter 380. The organic material layer 350 may be formed of one or more selected from acrylic resin, epoxy resin, polyimide, polyethylene, and silicon oxy carbide (SiOC), but embodiments of the present disclosure are not limited thereto. In this case, the structure columns 351 and 352 may be formed by coating the organic material layer 350 on the touch buffer layer 348, molding structure column form in the organic material layer 350, and then, performing UV curing.

The plurality of reflective patterns 363 and 364 may be provided on the surfaces of the plurality of structure columns 351 and 352. Specifically, referring to FIG. 18, a plurality of reflective patterns 363 may be formed on top surfaces 351a and side surfaces 351b of a plurality of structure columns 351. A plurality of reflective patterns 364 may be formed on top surfaces 352a and side surfaces 352b of a plurality of structure columns 352. Specifically, referring to FIG. 18, in the black matrix 370 positioned in the boundary areas of the plurality of color filters 382, 384, and 386, a plurality of reflective patterns 363 may be formed on top surfaces 351a and side surfaces 351b of a plurality of structure columns 351. In the plurality of color filters 382, 384, and 386, a plurality of reflective patterns 364 may be formed on top surfaces 352a and side surfaces 352b of a plurality of structure columns 352. However, embodiments of the present disclosure are not limited thereto.

However, embodiments of the present disclosure are not limited thereto. The reflective patterns 363 and 364 may include low-resistance metal such as silver (Ag), aluminum (Al), copper (Cu), chromium (Cr), or nickel (Ni) or may include a conductive nano-material such as silver nanowire or carbon nanotube. Specifically, the reflective patterns 363 and 364 may be may be preferably formed of a conductive material having excellent reflection characteristics. However, embodiments of the present disclosure are not limited thereto.

First and second reflective patterns 363 and 364 may be formed by depositing a metal material on first and second structure columns 351 and 352 vertically downward and obliquely at a given angle. The first and second reflective patterns 363 and 364 may be formed on the top surfaces 351a and 352a and the side surfaces 352a and 352b of the first and second structure columns 351 and 352.

The black matrix 370 that covers the plurality of first structure columns 351 and the plurality of first reflective patterns 363 may be provided on the organic material layer 350. The black matrix 370 may serve as an anti-reflection layer that absorbs external light while maintaining luminance of light emitted from the light-emitting elements 130 high and minimizes reduction in visibility and contrast ratio of the organic light-emitting display device 100 due to external light.

The black matrix 370 may absorb external light. Accordingly, it is possible to minimize reduction in visibility and contrast ratio of the organic light-emitting display device 100 due to external light. The black matrix 370 may include base resin and a black material. For example, the base resin may be one or more selected from cardo-based resin, epoxy-based resin, acrylate-based resin, siloxane-based resin, and polyimide, but embodiments of the present disclosure are not limited thereto. The black material may be a black pigment selected from a carbon-based pigment, a metal oxide-based pigment, and an organic-based pigment. For example, the carbon-based pigment may be carbon black. For example, the metal oxide-based pigment may be titanium black (TiNxOy) or a Cu—Mn—Fe-based black pigment, but embodiments of the present disclosure are not limited thereto. For example, the organic-based pigment may be selected from lactam black, perylene black, and aniline black, but embodiments of the present disclosure are not limited thereto. Further, an RGB black pigment including a red pigment, a blue pigment, and a green pigment may be used as the black material, but embodiments of the present disclosure are not limited thereto.

The black matrix 370 may cover at least one first structure column 351 and second reflective pattern 363. The black matrix 370 may be provided along the boundary of the sub-pixels SP1, SP2, and SP3 (see FIG. 2). The black matrix 370 may be provided to overlap the bank 134. Accordingly, it is possible to minimize color mixture between the sub-pixels SP1, SP2, and SP3.

The black matrix 370 may include a plurality of openings. The plurality of openings may overlap the sub-pixels SP1, SP2, and SP3 (see FIG. 2), respectively. The plurality of openings may overlap the light emission areas of the plurality of sub-pixels SP1, SP2, and SP3, respectively, to transmit light emitted from the intermediate layers 136. For example, the black matrix 370 may be provided to overlap the banks 134, and the plurality of openings OA disposed between the black matrix 370 may overlap the light emission areas of the plurality of sub-pixels SP1, SP2, and SP3, respectively.

The organic light-emitting display device 100 may have a pull-back structure. Specifically, a width of the opening may be greater than a width of the light emission area. However, embodiments of the present disclosure are not limited thereto.

A width of the bank 134 that defines the light emission areas of the plurality of sub-pixels SP1, SP2, and SP3 may be greater than a width of the black matrix 370 that defines the openings. Accordingly, a width of the opening OA (see FIG. 13) may be greater than a width of each of the sub-pixels SP1, SP2, and SP3. In this case, since part of light emitted from the light-emitting element 130 may be output to the side surface, a viewing angle luminance and a color viewing angle can be excellent. However, embodiments of the present disclosure are not limited thereto.

A plurality of color filters 380 may be provided on the organic material layer 350 positioned in the openings of the black matrix 370. For example, in the openings OA of the black matrix 370, the plurality of color filters 380 may be provided on the organic material layer 350. Each of the plurality of color filters 380 may include a first color filter 382, a second color filter 384, and a third color filter 386.

Here, at least one second structure column 352 may be provided in lower portions of the first to third color filters 382, 384, and 386. In this case, the second structure column 352 may be formed to protrude from a top surface of the organic material layer 350 in the vertical direction. For example, at least one second structure column 352 may be provided in lower portions of the black matrix 370 and the first to third color filters 382, 384, and 386.

Referring to FIG. 18, at least one first and second structure columns 351 and 352 and at least one first and second reflective patterns 363 and 364 may be provided in the black matrix 370 and the color filters 382, 384, and 386. The first structure columns 351 in the black matrix 370 may have a third height H3, and the first reflective patterns 363 in the black matrix 370 may have a third thickness T3. The first structure columns 351 may be spaced apart from each other at a third interval W3.

The second structure columns 352 in the color filters 382, 384, and 386 may have a fourth height H4, and the second reflective patterns 364 in the color filters 382, 384, and 386 may have a fourth thickness T4. The second structure columns 352 may be spaced apart from each other at a fourth interval W4. Embodiments of the present disclosure are not limited thereto.

Here, the third height H3 of the first structure columns 351 in the black matrix 370 may be higher than the fourth height of the second structure columns 352 in the color filters 382, 384, and 386. Embodiments of the present disclosure are not limited thereto.

The third thickness T3 of the first reflective patterns 363 in the black matrix 370 and the fourth thickness T4 of the second reflective patterns 364 in the color filters 382, 384, and 386 may be the same or different from each other. Embodiments of the present disclosure are not limited thereto.

The third interval W3 between the first structure columns 351 in the black matrix 370 may be narrower than the fourth interval W4 between the second structure columns 352 in the color filters 382, 384, and 386. However, embodiments of the present disclosure are not limited thereto. For example, the third interval W3 between the first structure columns 351 in the black matrix 370 may be the same as the fourth interval W4 between the second structure columns 352 in the color filters 382, 384, and 386 as necessary. For example, the third interval W3 between the first structure columns 351 in the black matrix 370 may be narrower than or equal to the fourth interval W4 between the second structure columns 352 in the color filters 382, 384, and 386.

The first and second reflective patterns 363 and 364 may be provided on the first and second structure columns 351 and 352, respectively. Referring to FIG. 18, the first and second reflective patterns 363 and 364 may be formed on the top surfaces 351a and 352a and the side surfaces 351a and 352b of the first and second structure columns 351 and 352, respectively.

The plurality of color filters 382, 384, and 386 may be provided corresponding to the light emission areas of the corresponding sub-pixels SP1, SP2, and SP3 (see FIG. 2).

Accordingly, internal light emitted from the first sub-pixel SP1, the second sub-pixel SP2, and the third sub-pixel SP3 may be transmitted through the color filters 382, 384, and 386, respectively. For example, red light emitted from the first sub-pixel SP1 may be transmitted through the first color filter 382. For example, green light emitted from the second sub-pixel SP2 may be transmitted through the second color filter 384. For example, blue light emitted from the third sub-pixel SP3 may be transmitted through the third color filter 386.

On the other hand, when external light is incident, external light corresponding to the absorption wavelengths of the color-development material included in the respective color filters 382, 384, and 386 may be absorbed by the color filters 382, 384, and 386. External light that is not absorbed by the color filters 382, 384, and 386 may be reflected by the cathodes 138 and may be transmitted through the color filters 382, 384, and 386 again. Reflected light corresponding to the absorption wavelengths of the color-development material included in the respective color filters 382, 384, and 386 may be absorbed by the color filters 382, 384, and 386. Accordingly, it is possible to minimize reduction in display quality due to external light.

In this way, according to the exemplary embodiments of the present disclosure, it is possible to recycle light vertically downward by reflecting part of light emitted from the light-emitting elements via the reflective patterns on the structure columns.

According to the exemplary embodiments of the present disclosure, it is possible to improve luminance by reflecting and condensing part of light absorbed by the black matrix out of light emitted from the light-emitting elements via the reflective patterns on the structure columns in the black matrix.

According to the exemplary embodiments of the present disclosure, it is possible to improve viewing angle characteristics as the height of the structure columns in the black matrix increases.

According to the exemplary embodiments of the present disclosure, as the interval between the structure columns in the color filter area is smaller and the height of the structure column is smaller, front luminance can be higher.

In summary, the disclosed organic light-emitting display device introduces structure columns with reflective patterns formed in both the black matrix and the color filter regions. The reflective patterns, provided on the top and side surfaces of the structure columns, recycle light emitted from the light-emitting elements and redirect light that would otherwise be absorbed by the black matrix. This configuration improves luminance and enhances light transmittance through the color filters while maintaining the black matrix's ability to absorb external light and prevent color mixing between sub-pixels.

Optical performance can be finely tuned by adjusting the height (H) of the structure columns, the interval (W) between adjacent columns, and the thickness (T) of the reflective patterns. Increasing the column height in the black matrix improves viewing angle characteristics, while varying the interval between columns in the color filter region induces plasmon resonance effects for wavelength-selective reflection, thereby enhancing color reproducibility. These features allow the device to achieve higher front luminance and better angular uniformity without sacrificing contrast.

As previously discussed, the present disclosure provided multiple embodiments to optimize performance and simplify manufacturing. In one embodiment, the structure columns are formed from an organic material layer, while in another they are integrated directly into the touch buffer layer, reducing process steps. A third embodiment differentiates the design of columns in the black matrix versus the color filter regions to achieve tailored optical effects. These innovations are well suited for color filter on encapsulation (CoE) structures, enabling slim, flexible displays with improved luminance, contrast ratio, and minimized color shift compared to conventional OLED architectures.

Although the exemplary embodiments of the present disclosure have been described in more detail with reference to the accompanying drawings, the present disclosure is not necessarily limited to such embodiments, and may be variously modified within the scope thereof without departing from the technical spirit of the present disclosure.

Accordingly, the exemplary embodiments disclosed herein are provided for illustrative purposes and are not intended to limit the technical concept of the present disclosure, and the scope of the technical concept of the present disclosure is not limited to these embodiments.

Therefore, it should be understood that the exemplary embodiments described above are illustrative in all aspects and are not intended to be limiting.

The scope of protection of the present disclosure should be construed on the basis of the following claims, and all technical concepts within the equivalent scope thereof should be construed as falling within the scope of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An organic light-emitting display device comprising:
a substrate having a plurality of sub-pixels;
a plurality of light-emitting elements provided on the substrate to correspond to the plurality of sub-pixels;
a bank provided in a boundary area of the plurality of light-emitting elements and defining a light emission area;
a black matrix overlapping the bank and having a plurality of openings;
a color filter provided in the plurality of openings of the black matrix;
a plurality of structure columns provided in the black matrix and the color filter; and
a plurality of reflective patterns provided on the plurality of structure columns.

2. The organic light-emitting display device according to claim 1, further comprising:
an encapsulation layer provided on the plurality of light-emitting elements and the bank;
a buffer layer provided on the encapsulation layer; and
an organic material layer provided on the buffer layer;
wherein the black matrix is provided on the buffer layer, and
wherein the plurality of structure columns protrude from a top surface of the organic material layer in a vertical direction.

3. The organic light-emitting display device according to claim 2, wherein the plurality of structure columns protrude from a top surface of the buffer layer in a vertical direction.

4. The organic light-emitting display device according to claim 1, wherein the plurality of reflective patterns are provided over top surfaces and side surfaces of the plurality of structure columns.

5. The organic light-emitting display device according to claim 1, wherein the plurality of structure columns include first structure columns in the black matrix and second structure columns in the color filter.

6. The organic light-emitting display device according to claim 5, wherein the first structure columns in the black matrix have the same height as or a height different from the second structure columns in the color filter.

7. The organic light-emitting display device according to claim 5, wherein the height of the first structure columns is higher than the height of the second structure columns.

8. The organic light-emitting display device according to claim 5, wherein an interval between the first structure columns in the black matrix is the same as or different from an interval between the second structure columns in the color filter.

9. The organic light-emitting display device according to claim 5, wherein the interval between the first structure columns is narrower than the interval between the second structure columns.

10. The organic light-emitting display device according to claim 1, wherein a width of the bank that defines light emission areas of the plurality of sub-pixels is greater than a width of the black matrix that defines the plurality of openings.

11. The organic light-emitting display device according to claim 1, wherein the reflective patterns is formed by depositing a metal material on the structure columns vertically downward and obliquely at a given angle.

12. The organic light-emitting display device according to claim 1, wherein part of the light emitted from the plurality of light-emitting elements is brought into contact with side surfaces of the reflective patterns on the structure columns in the color filter and is reflected.

13. An organic light-emitting display device comprising:
a substrate having a plurality of sub-pixels;
a plurality of light-emitting elements provided on the substrate to correspond to the plurality of sub-pixels;
an encapsulation layer provided on the plurality of light-emitting elements;
a black matrix that is provided on the encapsulation layer and has a plurality of openings corresponding to the plurality of light-emitting elements;
a plurality of color filters provided in the plurality of openings;
a plurality of structure columns provided in the black matrix and the plurality of color filters; and
a plurality of reflective patterns provided on the plurality of structure columns.

14. The organic light-emitting display device according to claim 13, further comprising an organic material layer provided on the encapsulation layer, wherein the plurality of structure columns protrude from a top surface of the organic material layer in a vertical direction.

15. The organic light-emitting display device according to claim 13, further comprising a buffer layer provided on the encapsulation layer, wherein the plurality of structure columns protrude from a top surface of the buffer layer in a vertical direction.

16. The organic light-emitting display device according to claim 15, wherein the plurality of structure columns and the buffer layer are formed of the same material layer.

17. The organic light-emitting display device according to claim 13, wherein the plurality of reflective patterns are provided over top surfaces and side surfaces of the plurality of structure columns.

18. The organic light-emitting display device according to claim 13, wherein the plurality of structure columns include first structure columns in the black matrix and second structure columns in the color filters.

19. The organic light-emitting display device according to claim 18, wherein the first structure columns in the black matrix have the same height as the second structure columns in the color filters or the height of the first structure columns is higher than the height of the second structure columns.

20. The organic light-emitting display device according to claim 18, wherein an interval between the first structure columns in the black matrix is the same as an interval between the second structure columns in the color filters, or
wherein the interval between the first structure columns is narrower than the interval between the second structure columns.
